(19) United States
(12) Patent Application Publication
(10) Pub. No.: US 2013/0287881 A1
(43) Pub. Date: Oct. 31, 2013

(54) IMPRINT MOLD FOR MANUFACTURING BIT-PATTERNED MEDIUM AND MANUFACTURING METHOD OF THE SAME

(71) Applicants: Hiromasa Iyama, Shinjuku-ku (JP); Hideo Kobayashi, Shinjuku-ku (JP)

(72) Inventors: Hiromasa Iyama, Shinjuku-ku (JP); Hideo Kobayashi, Shinjuku-ku (JP)

(73) Assignee: HOYA CORPORATION, Shinjuku-ku, Tokyo (JP)

(21) Appl. No.: 13/882,956

(22) PCT Filed: Nov. 1, 2011
(86) PCT No.: PCT/JP2011/075180

§ 371 Date: Jul. 16, 2013

(30) Foreign Application Priority Data
Nov. 2, 2010 (JP) 2010-245911

(51) Int. Cl. B29C 59/02; G03F 7/20

(52) U.S. Cl. CPC B29C 59/02; G03F 7/2051
USPC 425/385; 264/220; 430/296

(57) ABSTRACT

There is provided an imprint mold for manufacturing a bit-patterned medium with an imprint method, wherein dot-shaped protrusions are formed on a main surface of a substrate, so as to be a base of a magnetic material region in the bit-patterned medium, with the dot-shaped protrusions formed at a specific cycle in a specific direction on the main surface of the substrate, wherein the dot-shaped protrusions are formed by being surrounded by lattice-shaped grooves formed by shaving the main surface of the substrate and making a plurality of continuous planar view line-shaped grooves cross each other; and a width of each line-shaped groove is smaller than a width of each dot-shaped protrusion in the specific cycle.

### TECHNICAL FIELD

The present invention relates to an imprint mold for manufacturing a bit-patterned medium and a manufacturing method of the same.

### DESCRIPTION OF RELATED ART

Conventionally, in a magnetic medium used for a hard disc, etc., there is a technique of making magnetic particles finer, and minimizing a width of a magnetic head, and narrowing a space between data tracks in which information is recorded, to thereby obtain a higher recording density. Meanwhile, there is a more request for the higher recording density, and a magnetic influence on the space between adjacent tracks cannot be ignored in this magnetic medium. Therefore, in the conventional technique, there is a limit in the higher recording density.

In recent years, there is proposed a medium of a new type such as a patterned medium formed by magnetically separating the data tracks of the magnetic medium. The patterned medium aims at a further higher recording density by removing (grooving) a magnetic material in a part unnecessary for recording, thereby improving a signal quality.

In recent years, Discrete Track Recording Medium (called DTR medium hereafter) formed by magnetically separating the data tracks of the magnetic disc, is proposed as the patterned medium.

The DTR medium is excellent in S/N ratio (signal noise ratio), because a magnetic material region and a non-magnetic material region are physically separated by grooves.

Meanwhile, the medium of a new type is also proposed as “a bit-patterned medium” (called BPM hereafter, for recording a signal as a bit-pattern (dot pattern)) in which further higher density of the DTR medium is realized and further developed DTR medium is achieved.

As such a technique of mass-producing the patterned medium, an imprint technique (or called a nano-imprint technique) is publicly-known. This is a technique of fabricating a patterned medium by transferring a pattern of a master mold or a copy mold (called a working replica) which is obtained by transferring and copying the master mold once or a plurality of times, with the master mold as an original mold, to a transferred body (BPM here).

Note that the above-mentioned imprint technique is a technique of transferring to the transferred body, the pattern formed on a mold being an original mold. Various techniques are publicly-known as the technique of preparing the mold being the original mold. Among them, there is a technique of shaving a substrate so as to have a prescribed pattern shape by etching the substrate itself, and the substrate thus obtained is used as an original mold (for example, see patent document 1).

If simply speaking, the patent document 1 describes a technique of forming a resist on a surface of a quartz substrate, then exposing a part of a resist film corresponding to a specific pattern shape, which is then developed, to thereby form a resist pattern, and thereafter, etching the substrate based on the resist pattern, to thereby obtain an original mold of the substrate after removing the resist pattern.

Meanwhile, there is also the imprint technique described in patent document 2, although this is a technique different from the technique of shaving the substrate itself as described in the present invention.

If simply speaking, the patent document 2 describes a technique of forming a positive resist on a surface of a Si substrate, and exposing a part of the resist film corresponding to a bit-pattern, which is then developed, to thereby form a resist pattern, and thereafter forming a conductive film and an electroforming film from the resist pattern, to thereby form the electroforming film as a father stamper.

### PRIOR ART DOCUMENT

### Patent Document

Patent document 1:

Japanese Patent Laid Open Publication No.2008-310944

Patent document 2:

Japanese Patent Laid Open Publication No.2008-34024

### SUMMARY OF THE INVENTION

### Problem to be Solved by the Invention

The mold for producing the BPM is fabricated by exposure-drawing a bit-pattern portion by electron beams as described in patent document 1 and patent document 2.

Namely, when a pillar-shaped bit-pattern (pillar array) is desired to be formed on a master mold, the bit-pattern portion is exposure-drawn using a negative resist with electron beam writing.

Reversely, when a hole-shaped bit-pattern (hole array) is desired to be formed on the master mold, the bit-pattern portion is exposure-drawn by electron beams using a positive resist as described in patent document 2.

However, the above-mentioned method involves a problem as follows.

Namely, when the pillar bit-pattern is formed, the resist pattern of the pillar array is formed by using the negative resist. In this case, since exposure is performed for each pillar bit, the columnar pillar is formed in such a manner as being separated from each other. As a result, in a case of a development and etching applied to the substrate, there is a risk of causing a part of the pillar array to fall down. When such a fall-down of the pillar array occurs in the resist pattern, a pattern defect is generated in the mold being the original mold during etching performed to the substrate. Then, such a pattern defect is transferred to a transferred body from the original mold.

Meanwhile, when the hole-shaped bit-pattern is formed, the resist pattern of the hole array is formed when using the positive resist. In this case, since the exposure is performed for each hole-shaped bit, the hole array is supposed to be formed, with each hole separated from each other originally. However, there is a possibility that holes are connected to each other in a part of the hole array, which leads to a generation of the pattern defect, similarly to a case of the pillar-shaped bit-pattern.

Such a pattern defect leads to the pattern defect in BPM consequently, thus possibly having a serious influence on a yield of a final product.

Further, such a problem is required to be solved, and there is a further request for improving the higher recording density (higher S/N), namely there is a further request for a narrowed and finer pattern (bit) pitch.

An object of the present invention is to provide an imprint mold and a manufacturing method of the same, capable of manufacturing BPM having high S/N, and suppressing a generation of a pattern defect, and which can be manufactured relatively in a short time.

### Means for Solving the Problem

Inventors of the present invention examine a mold being an original mold for fabricating BPM by imprint. Further specifically, how much the above-mentioned pattern defect can be reduced, is examined in the mold with a bit-pattern formed on a main surface of a substrate by shaving the main surface of the substrate.

As a result of the examination, the inventors of the present invention obtain a knowledge that a lattice-shaped exposure is performed to the resist without exposing a dot-shaped portion as conventional, to thereby form a bit-pattern in a portion surrounded by the lattice. More specifically, the inventors of the present invention obtain an unconventional knowledge in at least in a field of the imprint technique. Namely, this is a technique of not forming the bit-pattern by dot-shaped exposure, but forming the bit-pattern by line-shaped exposure on the main surface of the substrate by shaving the substrate (namely, “dot (bit))” is fabricated by “line”).

As a result, it is found that not only realizing the reduction of the pattern defect being an original problem, but also expanding an area of a magnetic portion in BPM, can be realized, and the S/N ratio can be improved.

Based on this knowledge, the inventors of the present invention achieve a solution to solve the above-mentioned problem.

Based on such a knowledge, the present invention has following aspects.

According to a first aspect of the present invention, there is provided an imprint mold for manufacturing a bit-patterned medium with an imprint method, wherein dot-shaped protrusions are formed on a main surface of a substrate, so as to be a base of a magnetic material region in the bit-patterned medium, with the dot-shaped protrusions formed at a specific cycle in a specific direction on the main surface of the substrate,
wherein the dot-shaped protrusions are formed by being surrounded by lattice-shaped grooves formed by shaving the main surface of the substrate and making a plurality of continuous planar view line-shaped grooves cross each other; and
a width of each line-shaped groove is smaller than a width of each dot-shaped protrusion in the specific cycle.

According to a second aspect of the present invention, there is provided the imprint mold of the first aspect, wherein the specific cycle is 25 nm or less, and the width of the line-shaped groove is ⅔ or less of the width of the dot-shaped protrusion.

According to a third aspect of the present invention, there is provided the imprint mold of the first or second aspect, wherein the substrate is a transparent or semitransparent substrate.

According to a fourth aspect of the present invention, there is provided the imprint mold of any one of the first to third aspects, wherein the substrate is made of quartz.

According to a fifth aspect of the present invention, there is provided the imprint mold of any one of the first to fourth aspects, for manufacturing the bit-patterned medium with the imprint method, wherein the dot-shaped protrusions are formed on the main surface of the substrate, so as to be the base of the magnetic material region in the bit-patterned medium, with the dot-shaped protrusions formed in a specific direction at a specific cycle of 25 nm or less on the main surface of the substrate, and the substrate is a transparent or semi-transparent substrate,
wherein the dot-shaped protrusions are formed by being surrounded by the lattice-shaped grooves formed by shaving the main surface of the substrate and making a plurality of continuous planar view line-shaped grooves cross each other, with the width of each line-shaped groove is ⅔ or less of the width of each dot-shaped protrusion.

According to a sixth aspect of the present invention, there is provided an imprint mold for manufacturing a bit-patterned medium with an imprint method, wherein dot-shaped recesses are formed on the main surface of the substrate, so as to be a base of a magnetic material region in the bit-patterned medium, with the dot-shaped recesses formed at a specific cycle in a specific direction on the main surface of the substrate,
wherein the dot-shaped recesses are formed by surrounding the shaved portion on the surface of the substrate by lattice-shaped wall parts formed by making a plurality of continuous planar view line-shaped walls cross each other, and
a width of each line-shaped wall is smaller than a width of each dot-shaped recess in the specific cycle.

According to a seventh aspect of the present invention, there is provided an imprint mold for manufacturing a bit patterned medium, wherein an imprint mold is fabricated by imprint using the imprint mold for manufacturing a patterned medium of any one of the first to sixth aspects.

According to an eighth aspect of the present invention, there is provided a manufacturing method of an imprint mold for manufacturing a bit-patterned medium, with dot-shaped protrusions formed on a main surface of a substrate in such a manner as being separated for every one bit, so as to be a base of a magnetic material region in the bit-patterned medium, wherein the dot-shaped protrusions are formed in a specific direction at a specific cycle on the main surface of the substrate, the method including:
coating a positive resist so as to cover the main surface of the substrate;
performing lattice-shaped exposure after coating, to the main surface of the substrate covered with the positive resist by making a plurality of line-shaped exposure candidate parts cross each other, and forming lattice-shaped exposure candidate parts and dot-shaped non-exposure parts surrounded by the lattice-shaped exposure candidate parts;
forming a resist pattern by developing the positive resist after exposure; and
forming a bit-pattern including dot-shaped protrusions on the main surface of the substrate by etching, after development,
wherein in the exposure, the exposure is performed so that a width of each line-shaped exposure candidate part is smaller than a width of each dot-shaped non-exposure part in the specific cycle, and
the dot-shaped protrusions are finally formed by line-shaped exposure, on the main surface of the substrate in such a manner as being separated for every one bit.

According to a ninth aspect of the present invention, there is provided the imprint mold of the eighth aspect, wherein the exposure is performed by electron bean drawing performed to the main surface of the substrate covered with the positive resist.

According to a tenth aspect of the present invention, there is provided the imprint mold of eighth or ninth aspect, wherein the specific cycle is set to 25 nm or less, and the width of each line-shaped exposure candidate part is set to ⅔ or less of the width of each dot-shaped non-exposure part.

According to an eleventh aspect of the present invention, there is provided the imprint mold of any one of the eighth to tenth aspects, wherein the substrate is a transparent or semi-transparent substrate.

According to a twelfth aspect of the present invention, there is provided the imprint mold of any one of the eighth to eleventh aspects, wherein the substrate is made of quartz.

According to a thirteenth aspect of the present invention, there is provided the imprint mold of any one of the eighth to twelfth aspects, for manufacturing a bit-patterned medium with an imprint method, wherein dot-shaped protrusions are formed on the main surface of the substrate, so as to be a base of a magnetic material region in the bit-patterned media, with the dot-shaped protrusions formed in a specific direction at a specific cycle of 25 nm on the main surface of the substrate, and the substrate is a transparent or semi-transparent substrate, the method including:
coating a positive resist so as to cover the main surface of the substrate;
performing lattice-shaped exposure after coating, to the main surface of the substrate covered with the positive resist by making a plurality of line-shaped exposure candidate parts cross each other, and forming lattice-shaped exposure candidate parts and dot-shaped non-exposure parts surrounded by the lattice-shaped exposure candidate parts;
forming a resist pattern by developing the positive resist after exposure; and
forming a bit-pattern on the main surface of the substrate by etching after development,
wherein in the exposure, the exposure is performed so that a width of each line-shaped exposure candidate part is ⅔ or less of a width of each dot-shaped non-exposure part, and
the dot-shaped protrusions are finally formed by line-shaped exposure, on the main surface of the substrate in such a manner as being separated for every one bit.

According to a fourteenth aspect of the present invention, there is provided a manufacturing method of an imprint mold for manufacturing a bit-patterned medium, for manufacturing a bit-patterned medium with an imprint method, wherein dot-shaped recesses are formed on a main surface of a substrate in such a manner as being separated for every one bit, so as to be abase of a magnetic material region in a bit-patterned medium, with the dot-shaped recesses formed in a specific direction at a specific cycle on the main surface of the substrate, the method including:
coating a positive resist so as to cover the main surface of the substrate;
performing lattice-shaped exposure after coating, to the main surface of the substrate covered with the positive resist by making a plurality of line-shaped exposure candidate parts cross each other, and forming lattice-shaped exposure candidate parts and dot-shaped non-exposure parts surrounded by the lattice-shaped exposure candidate parts;
forming a lattice-shaped resist pattern by developing the negative resist after exposure; and
forming a bit-pattern including dot-shaped recesses on the main surface of the substrate by etching, after development,
wherein in the exposure, the exposure is performed so that a width of each line-shaped exposure part is smaller than a width of each dot-shaped non-exposure part in the specific cycle, and
the dot-shaped recesses are finally formed by line-shaped exposure, on the main surface of the substrate in such a manner as being separated for every one bit.

According to a fifteenth aspect of the present invention, there is provided a manufacturing method of an imprint mold for manufacturing a bit-patterned medium, wherein the imprint mold fabricated by the manufacturing method of an imprint mold for manufacturing a patterned medium described in any one of the eighth to fourteenth aspects, is used as an original mold, to thereby fabricate the imprint mold by imprint.

### Advantage of the Invention

According to the present invention, there is provided an imprint mold and a manufacturing method of the same, capable of manufacturing BPM having a high S/N, suppressing a generation of a pattern defect, and which can be manufactured relatively in a short time.

### BRIEF DESCRIPTION OF THE DRAWINGS

FIG. 1 is a schematic cross-sectional view showing a manufacturing process of a master mold according to an embodiment.

FIG. 2 is a schematic planar view showing an exposed portion on a resist layer according to a modified example of the present invention, wherein FIG. 2(a) is a view showing exposure candidate parts, and FIG. 2(b) shows actually exposed portions and non-exposure parts excluding the description of the exposure candidate parts.

FIG. 3 is a schematic planar view showing exposed portions on the resist layer according to a modified example of the present invention.

FIG. 4(a) is a schematic planar view showing the exposed portions on a positive resist layer when fabricating an imprint mold having lattice-shaped grooves, and FIG. 4(b) is a schematic perspective view of the imprint mold having the lattice-shaped grooves according to an embodiment.

FIG. 5 is a schematic cross-sectional view showing a manufacturing process of a working replica according to an embodiment.

FIG. 6(a) is a schematic planar view showing developed portions of the positive resist layer, when fabricating the imprint mold having lattice-shaped grooves according to a modified example of the present invention, and FIG. 6(b) is a schematic perspective view showing the imprint mold having the lattice-shaped grooves according to a modified example of the present invention.

FIG. 7(a) is a schematic planar view showing the exposed portions on a negative resist layer, when fabricating the imprint mold having lattice-shaped wall parts according to an embodiment of the present invention, and FIG. 7(b) is a schematic perspective view in a case of forming a lattice-shaped resist pattern on a substrate, and FIG. 7(c) is a schematic perspective view in a case of applying etching to the substrate, and FIG. 7(d) is a schematic perspective view of the imprint mold having the lattice-shaped wall parts.

### MODES FOR CARRYING OUT THE INVENTION

In this embodiment, explanation is given for a case that an original mold (master mold) on which a bit pattern is formed, is fabricated, and a working replica is fabricated by copying the master mold once or a plurality of times, with the master mold as an original mold. Also, explanation is given for a case that the bit pattern of the working replica is transferred by an imprint technique, to thereby fabricate a BPM. Further, in this embodiment, detailed explanation is given for a case that a cycle of the bit pattern is less than 1 μm. Therefore, the imprint technique is called a nanoimprint technique or is simply called a nanoimprint. Note that the “master mold” and the “working replica” are collectively simply called a “mold”.

Embodiments of the present invention will be described hereafter in detail, with reference to the drawings.

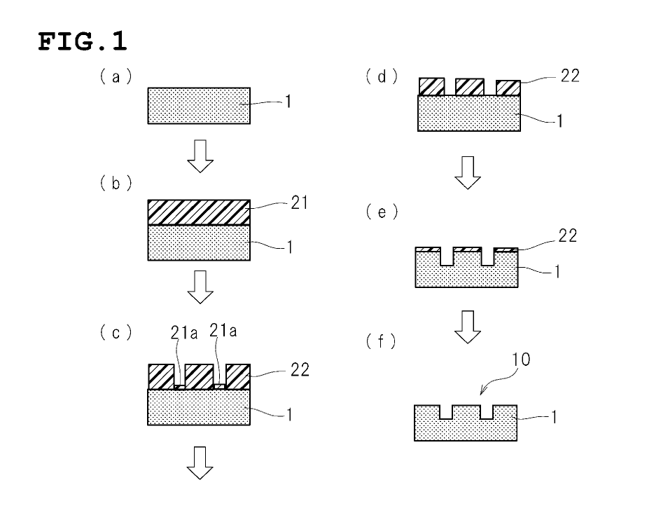

In this embodiment, FIG. 1 is used first, and explanation is given in the following order.
1. Manufacturing Method of a Master Mold
   a) Preparation of a Substrate
   b) Resist Coating Step
   c) Exposure Step
   d) Development Step
   e) Etching Step Performed to the Substrate
   f) Washing/Drying Step
2. Details of the Bit Pattern on the Main Surface of the Master Mold
3. Manufacturing Method of a Working Replica Based on the Master Mold
   a) Preparation of a Substrate for Manufacturing a Working Replica
   b) Formation of a Resist Layer
   c) Placement of the Original Mold on the Resist Layer
   d) Pattern Transfer by Exposure
   e) Removal of a Residual Film Layer on the Resist Layer
   f) Etching Applied to the Substrate
   g) Completion of the Working Replica
4. Manufacturing Method of BPM Based on the Working Replica
5. Effect of the Embodiment
6. Modified Example
<1. Manufacturing Method of a Master Mold>
   a) Preparation of a Substrate

In this embodiment, a substrate 1 of FIG. 1(a) is a substrate for manufacturing a magnetic recording medium having a plurality of tracks, or to be a master mold (original mold) 10 used for manufacturing the magnetic recording medium having a plurality of tracks by imprint. Namely, this is a substrate to be an imprint mold for manufacturing a bit-patterned medium with an imprint method.

In this embodiment, explanation is given by using a wafer-shaped substrate 1 made of quartz. The wafer-shaped substrate 1 made of quartz is simply called a substrate 1 hereafter.

Note that in this embodiment, although the substrate 1 has a wafer shape, schematic explanation is given for a case that the substrate 1 is a rectangular substrate in the drawings, for the convenience of describing an outline of the invention so as to be easy to be understood.
b) Resist Coating Step

Dehydration baking treatment is applied to the substrate 1, and an adhesive auxiliary layer (not shown) is formed. Thereafter, as shown in FIG. 1(b), a resist layer 21 is formed so as to cover a main surface, being one of the surfaces of the substrate 1, as an example of a photosensitive film in a coating step. In this embodiment, positive resist is used for the resist layer 21 as an example.

Note that explanation is given in item <6. Modified example>, for a case of using a negative resist.

A spin coating method is used as a coating method, which is a method of dropping a solution of the resist on the main surface of the substrate 1 with a hard mask 2 formed thereon, and thereafter rotating the substrate 1 at a specific number of rotations, to thereby form the resist layer 21. Subsequently, baking treatment is applied to the substrate 1 with the resist layer 21 spin-coated thereon, at a specific temperature on a hot plate, and thereafter the substrate is transferred on a cooling plate having a temperate maintained to a room temperature (for example, 22.5° C.), and cooling treatment is applied thereto, and drying treatment is also applied thereto, to thereby form the resist layer 21.

Further, the resist film 21 in this case preferably has a thickness of allowing the resist layer to be remained until the etching for the substrate 1 is completed. This is because by such an etching applied to the substrate 1, not only a part corresponding to a resist dissolution part formed on the resist layer 21, but also the resist layer 21 of a resist non-dissolution part is substantially removed.
c) Exposure Step

After the coating step, a desired pattern is drawn on the resist layer 21, using an electron beam exposure (drawing) apparatus. Note that in this embodiment, as described above, the resist layer 21 is the positive resist. Therefore, an electron beam drawing part is the resist dissolution part, and consequently the electron beam drawing part corresponds to a lattice-shaped groove part 8 in the master mold 10. Note that drawing by electron beams is also called “exposure” or “electron beam exposure” hereafter.

Detailed explanation will be given hereafter.

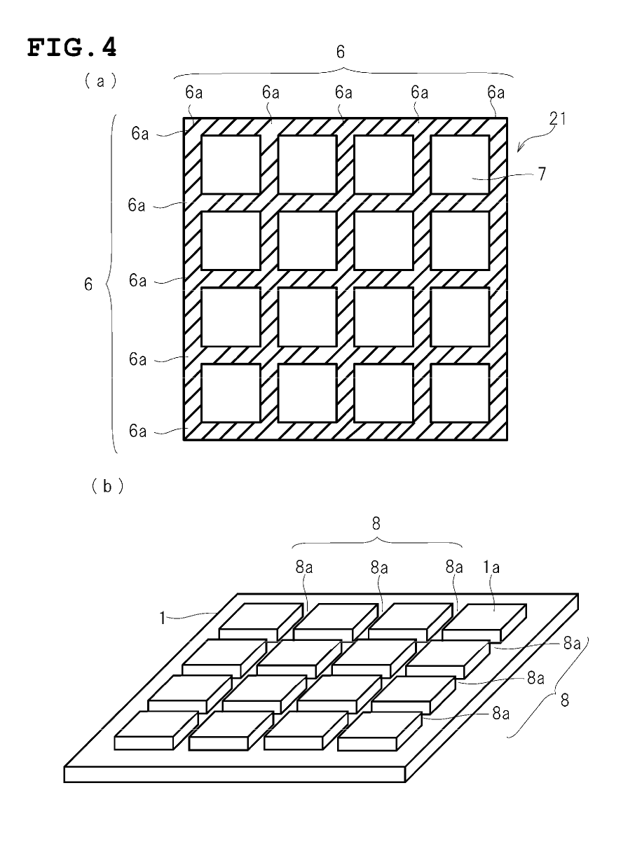

In this embodiment, as shown in FIG. 4(a), lattice-shaped exposure is performed to the main surface of the substrate 1 covered with the positive resist, by making a plurality of line-shaped exposure candidate parts 6 cross each other, to thereby form lattice-shaped exposure candidate parts 6 and dot-shaped non-exposure parts 7 surrounded by the lattice-shaped exposure candidate parts 6.

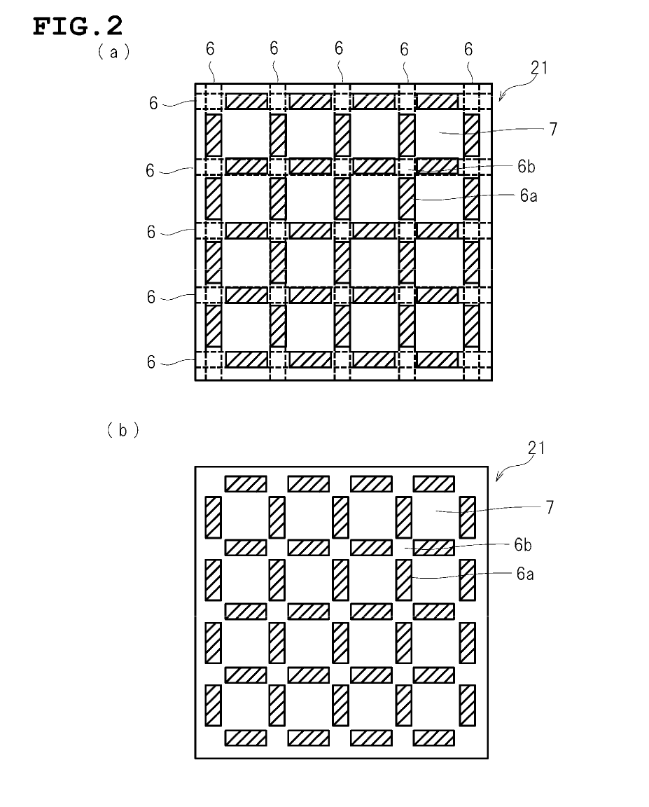

The “exposure candidate parts” called here are the parts where the exposure is possibly performed by the electron beam exposure apparatus. Namely, in the exposure candidate parts 6, there is a room left including not only exposed portions 6a but also unexposed portions 6b as a result after an actual exposure step, as shown in FIG. 2(a) and FIG. 2(b) showing the main surface of the substrate 1 covered with the positive resist. Thus, even in a case that the unexposed portions 6b exist in the exposure candidate parts 6, dot-shaped protrusions 1a may be finally formed on the main surface of the substrate 1 in such a manner as being separated for every one bit as shown in FIG. 4(b) by the step thereafter.

Next, “line” in a plurality of line-shaped exposure candidate parts 6, includes a straight line and a curved line. Further, either a continuous line-shaped exposure or a discontinuous (for example, a broken-line shape in planar view) line-shaped exposure is acceptable. It is preferable to form the lattice-shaped exposure candidate parts 6 by making the plurality of exposure candidate parts 6 cross each other, and also it is preferable to form the dot-shaped non-exposure parts 7 by being surrounded by the lattice-shaped exposure candidate parts 6.

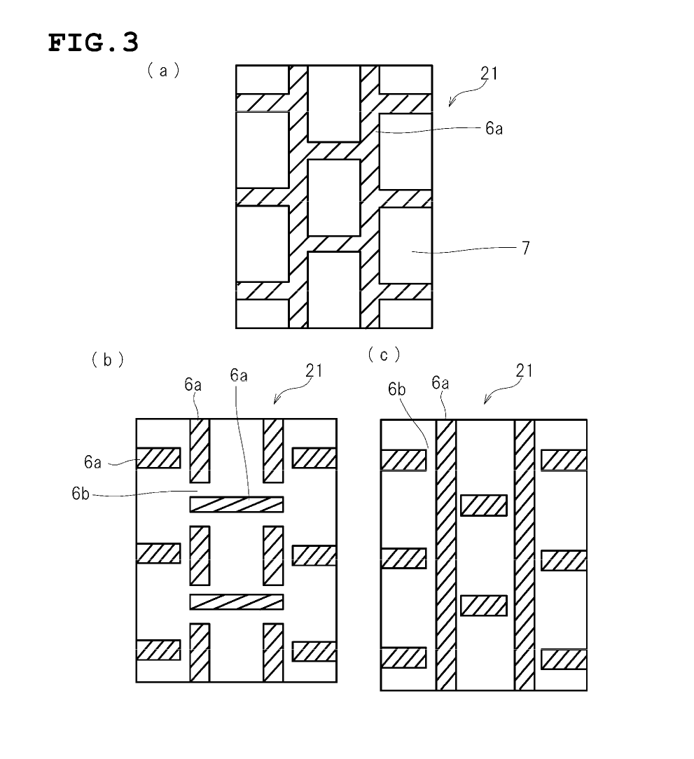

The “lattice-shaped exposure candidate parts” called here may be the parts where lattices are formed by making a plurality of planar view straight exposure candidate parts 6 cross each other as shown in FIG. 2(a). Further, similarly, as shown in FIG. 3(a) showing the main surface of the substrate 1 covered with the positive resist, the “lattice-shaped exposure candidate parts” may be the parts where the exposure candidate parts 6 are made to intersect each other without crossing each other, so as to form a planar view trifurcate road.

The “lattice-shape” called here indicates a state that the non-exposure parts 7 are surrounded by the “exposure candidate parts”. This state includes a case that the non-exposure parts 7 are completely surrounded only by the actually exposed portions 6a in the exposure step as shown in FIG. 4(a), and also includes the parts not completely surrounded by the actually exposed portions 6a as shown in FIG. 2(b), although being surrounded by the exposure candidate parts 6 as shown in FIG. 2(a).

In any case, continuous grooves can be formed on the main surface of the substrate by the etching step applied to the substrate as will be described later, and it is preferable to finally form the dot-shaped protrusions 1a on the main surface of the substrate 1 in such a manner as being separated for every one bit.

Note that <6. Modified example> indicates a case of the discontinuous line-shaped exposure, and a case that the exposure candidate parts 6 include a portion not exposed actually. This embodiment shows a case that exposure is performed to all portions of the exposure candidate parts 6.

As described above, in this embodiment, the exposure candidate parts 6 are entirely exposed actually (FIG. 4(a)). In this case, the exposure is performed so that the width of each line-shaped exposure candidate part is smaller than the width of each dot-shaped non-exposure part 7 in the specific cycle.

The resist of the portion of the dot-shaped protrusions 1a can be relatively largely left than conventional by exposing a “portion excluding” a bit portion, and further by setting the width of each line-shaped exposure candidate part 6 to be smaller than the width of each dot-shaped non-exposure part 7. As a result, even in a case that the resist is slightly lost when etching is performed to the substrate 1 thereafter, relatively large dot-shaped protrusions 1a can be formed (FIG. 4(b)).

Conventionally, there is an extremely strict condition setting such as setting the width of the exposure part and the width of the non-exposure part to be the “same” (namely, recess width:protrusion width=1:1, which are finally formed on the main surface of the substrate) in BPM and the mold used for manufacturing the BPM.

However, when the above-mentioned technique of this embodiment is used, the resist of the portions of the dot-shaped protrusions 1a can be sufficiently left, and difficulty in forming the bit pattern can be reduced, and consequently the generation of the pattern defect can be suppressed.

Further, BPM having a sufficiently large magnetic material region can be fabricated. It is not necessary to simultaneously expose a large bit corresponding to the sufficiently large magnetic material region every time the BPM is fabricated. Namely, it is sufficient to expose a small area (area of a portion excluding the bit portion), thus making it possible to considerably shorten a time required for the exposure.

As a result, the imprint mold capable of manufacturing the BPM having high S/N, and suppressing the generation of the pattern defect, and which can be manufactured in relatively a short time, can be provided.

Namely, as described in this embodiment, the above-mentioned effect can be obtained by exposing the portion “excluding the bit portion”, based on a concept that “dots” are fabricated by “lines”, to thereby obtain the above-mentioned effect.

Note that the length of the above-mentioned specific cycle is preferably set to less than 1 μm from a viewpoint of a performance of electronic equipment and a performance of a final product of recent years.

Further, particularly preferably, the specific cycle is set to 25 nm or less, and the width of each line-shaped exposure candidate part 6 is set to ⅔ of the width of each dot-shaped non-exposure part 7. The reason thereof is as follows.

Conventionally, when the bit pattern is formed in an extremely minute order of 25 nm, it can be considered that the bit pattern must be formed more finely.

In order to form the bit pattern more finely, the bit portion is usually exposed in the substrate covered with the resist layer, in even in a conventional circumstance that the ratio of the recess width and the protrusion width formed on the main surface of the substrate finally is 1:1. Therefore, when the bit pattern is formed in the extremely minute order of 25 nm, and when the width of the dot-shaped protrusion 1a is set to be large, the dot-shaped protrusion parts 1a must be further precisely arranged, and consequently the protrusion parts 1a are expected to be exposed by electron beams more precisely.

However, such a difficulty can be solved by exposing the portion “excluding the bit portion” based on an unconventional reverse concept (namely, the concept that “bits (dots))” are fabricated) by “lines” as described in this embodiment.

Namely, a large amount of the resist of the portion of the dot-shaped non-exposure parts 7 can be remained by exposing the portion “excluding the bit portion”, so that the width of each line-shaped exposure candidate part 6 is ⅔ of the width of the dot-shaped non-exposure parts 7. As a result, even if the resist is slightly lost when the etching treatment is applied to the substrate thereafter, sufficiently large dot-shaped protrusions la can be formed on the main surface of the substrate, and consequently BPM having a sufficiently large magnetic material region can be fabricated.

As a result, BPM having high S/N can be manufactured, and the generation of the pattern defect can be suppressed.

Note that the explanation is given for a case that the planar view shape of each non-exposure part 7 is substantially a rectangular shape in this embodiment. However, the non-exposure part 7 may have a shape if it can function as the magnetic material region in BPM. The shape can be a substantial circular shape or a substantial rectangular shape, or can be other shape, depending on an exposure mode in the exposure step.
d) Development Step
   (Development)

After a desired fine pattern is exposed, as shown in FIG. 1(c), the resist layer 21 made of positive resist is developed by a specific developing agent, and the exposed portion (resist dissolution part) in the resist layer 21 is removed, and resist a pattern 22 corresponding to the desired fine pattern is formed.
(Rinse/Dry)

Thereafter, a rinse agent is dropped and supplied from above the substrate 1 while rotating the substrate 1, for washing the developing agent, immediately after stopping the drop and supply of the developing agent. Thereafter, drying treatment is applied to the substrate 1 that is subjected to the rinse treatment. Thus, the substrate 1 can be obtained, in which the desired resist pattern 22 is formed including the resist dissolution part and the resist non-dissolution part.
e) Etching Step Applied to the Substrate

The bit pattern including the dot-shaped protrusions 1a is formed on the main surface of the substrate by etching, after the development step. The etching step is described hereafter.
(Descumming of the Resist Pattern: First Etching)

Thereafter, the substrate 1 with the resist pattern 22 formed thereon, is introduced to a dry etching device. Then, as shown in FIG. 1(d), a first etching is performed thereto using a mixed gas of an oxygen gas and an argon (Ar) gas, to thereby remove a residue (scum) being a residual film layer of the resist dissolution part.
(Etching of the Substrate: Second Etching)

Subsequently, the gas used for the first etching is exhausted, and thereafter a second etching is performed to the substrate 1 using a fluorine-based gas. Thus, as shown in FIG. 1(e), grooving corresponding to the resist pattern 22 is applied to the substrate 1, to thereby fabricate a mold in which the resist pattern 22 is remained in the portion excluding the grooves 8.
(Removal of the Resist Pattern)

Subsequently, a residue of the resist pattern 22 generated after the third etching is removed as shown in FIG. 1(f), by a resist release agent composed of a mixed solution of sulfuric acid and a hydrogen peroxide solution, to thereby completely release the resist pattern 22.

Specifically, the substrate 1 is immersed in the resist release agent for a specific time, and thereafter the resist release agent is washed by a rinse agent (here, pure water of a normal temperature or heated pure water). Subsequently, the substrate 1 is dried by a similar method as the method of the above-mentioned drying treatment.

As the resist release agent used here, a compound capable of making the resist swollen and dissolved, then chemically dissolved, released, and removed, may be used.
f) Washing/Drying Step

Washing, etc., of the substrate 1 is performed as needed, after the above-mentioned step. Thus, the master mold 10 as shown in FIG. 1(f) is completed.
<2. Details of the Bit Pattern on the Main Surface of the Master Mold>

The master mold 10 obtained after the above-mentioned step, will be described hereafter using FIG. 4(b).

Protrusions/recesses are formed on the master mold 10 in this embodiment, by shaving the main surface of the substrate by etching. Each protrusion 1a has a dot-shape. When the BPM having the magnetic material region is fabricated from the master mold 10 by imprint while having the above-mentioned dot-shape, the protrusion 1a is the portion so as to be a base of the magnetic material region.

The dot-shaped protrusions 1a are formed by being surrounded by the lattice-shaped grooves 8 formed by shaving the main surface of the substrate 1 and making a plurality of continuous planar view line-shaped grooves 8a cross each other. Further, the width of each line-shaped groove 8a is smaller than the width of each dot-shaped protrusion 1a in the specific cycle.

The “continuous line-shaped grooves” called here indicate each groove 8a constituting the “lattice-shaped grooves”, and the shape of the line does not matter, provided that the line is continuous.

Further, the grooves 8a in the “lattice-shaped grooves” may be arranged so as to be formed by making a plurality of continuous straight lines cross each other in a planar views. Also, the grooves may be made to intersect each other without crossing each other, so as to form a planar view trifurcate road.

Further, the “lattice-shaped grooves” are the portions formed by a combination of the “continuous line-shaped grooves”, which are the portions to form the dot-shaped protrusions 1a on the main surface of the substrate 1 by separating them for every one bit by its existence. Namely, the “lattice-shaped grooves” in this embodiment indicate an assembly of the grooves 8a formed so as to surround the dot-shaped protrusions 1a.

Conventionally, the width of the dot-shaped portion (magnetic material portion in BPM) is set to be equivalent to or less than the width of the portion excluding the dot-shaped portion (non-magnetic material portion in BPM) in a specific cycle of the pattern. Therefore, the area of the magnetic material portion in BPM is relatively small.

However, in a case of the print mold of this embodiment, a considerably large dot-shaped portion can be secured. As a result, the BPM having high S/N can be manufactured, and the generation of the pattern defect can be suppressed.

Note that the dot-shaped protrusions 1a are formed on the main surface of the substrate 1 in a specific direction at a specific cycle. The specific direction is an information reading direction (circumferential direction) in BPM in many cases. Of course, a radius direction or the other direction may also be acceptable.

The length of the specific cycle is preferably set to less than 1 μm as described in the <1. Manufacturing method of the master mold> c) exposure step, from the viewpoint of the performance of the electronic equipment and the performance of the final product of recent years. Note that particularly preferably, the specific cycle is set to 25 nm or less, and the width of each line-shaped groove 8a is set to ⅔ of the width of each dot-shaped protrusion 1a.

Further, the area of the dot-shaped protrusions 1a in a planar view is preferably set to be larger than ⅓ of the area of the lattice-shaped grooves 8, in the specific cycle (namely, in a region of one unit formed by the dot-shaped protrusions 1a and the lattice-shaped grooves 8). By setting such large dot-shaped protrusions la, a large region including the magnetic material portion in BPM can be finally secured, and the BPM having a sufficient S/N ratio can be fabricated.
<3. Manufacturing Method of a Working Replica Based on the Master Mold>

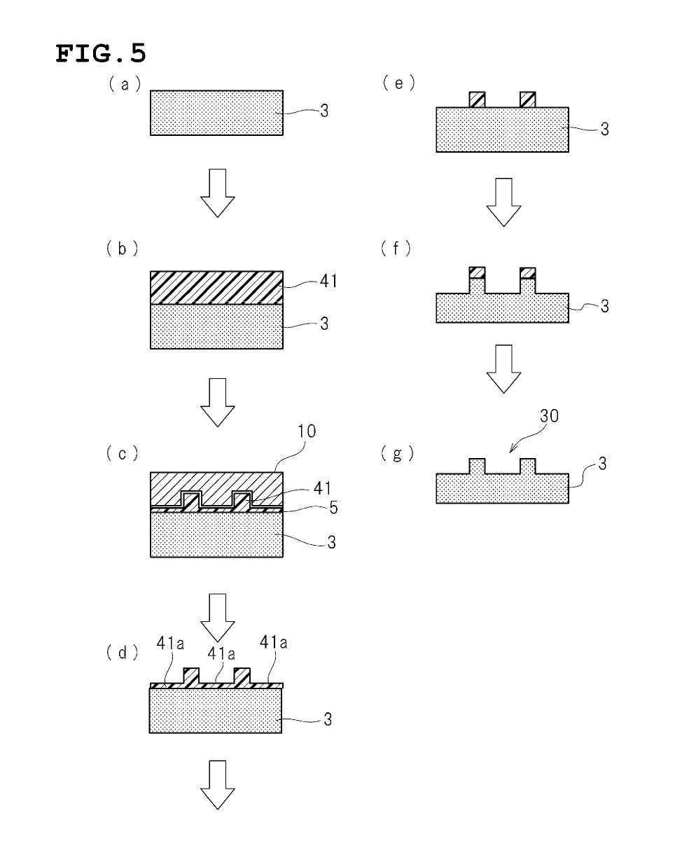

In this embodiment, a working replica fabrication step will be described in the following procedure, using FIG. 5.
a) Preparation of a substrate for manufacturing a working replica
b) Formation of the resist layer
c) Placement of the original mold on the resist layer
d) Pattern transfer by exposure
e) Removal of the residual film on the resist layer
f) Etching applied to the substrate
g) Completion of the working replica
   a) Preparation of a Substrate for Manufacturing a Working Replica

First, as shown in FIG. 5(a), a substrate 3 for a working replica 30 is prepared.

The substrate 3 may be made of the same material as the material of the above-mentioned master mold 10, provided that it can be used as the working replica 30.

In this embodiment, a disc-shaped quartz substrate 3 is used for explanation.
b) Formation of the Resist Layer

After suitably washing the substrate 3 and baking treatment is applied thereto, as shown in FIG. 5(b), the substrate 3 for the working replica 30 is coated with a resist for optical imprint and a resist layer 41 is formed, to thereby fabricate the resist layer 41-attached substrate 3 used for manufacturing the working replica 30 according to this embodiment.

Note that similarly to the case of the master mold 10, the hard mask or the adhesive auxiliary layer, etc., may be provided between the substrate 3 and the resist layer 41.

As the resist for optical imprint, photo-curing resin and particularly UV-curing resin can be given. However, the photo-curing resin suitable for the etching step performed later may be used. Further, any kind of resin other than the photo-curing resin may be used, provided that it is suitable for imprint, such as the resin for thermal imprint.

Further, the resist film 41 in this case preferably has a thickness of allowing the resist of a mask portion to be remained until each kind of etching is completed.
c) Placement of the Original Mold on the Resist Layer

After the baking treatment is suitably applied to the resist layer 41, as shown in FIG. 5(c), the master mold 10 with a fine pattern formed thereon and a mold release layer 5 formed thereon, is disposed on the resist layer 41.

In this case, if the resist layer 41 is in a liquid state, the master mold 10 may be simply placed thereon.

Further, if the resist layer 41 is in a solid state, a soft resist layer 41 may be satisfactory, so that the master mold 10 is pressed against the resist layer 41 and the fine pattern can be transferred thereto.
d) Pattern Transfer by Exposure

Thereafter, the fine pattern of the master mold 10 is transferred to the resist layer 41, using an ultraviolet light irradiation device. Exposure to the ultraviolet light is usually performed from the master mold 10 side. However, when the substrate 3 is a light-transmitting substrate, the exposure may be performed from the substrate 3 side.

Note that at this time, in order to prevent a transfer failure due to a positional deviation between the master mold 10 and the substrate 3, a groove for an alignment mark may be previously provided on the substrate 3.
After e) Removal of the Residual Film Layer on the Resist Layer

After transfer of the fine pattern, as shown in FIG. 5(d), the master mold 10 is released from the resist layer 41-attached substrate 3.

Then, the residual film layer 41a on the substrate 3 is removed by ashing using plasma of a gas such as ozone, etc., by a method described in the <1. Manufacturing method of the master mold> e) Etching step applied to the substrate (descumming of the resist pattern: first etching).

Thus, as shown in FIG. 5(e), the resist pattern 42 corresponding to desired fine pattern, is formed. Note that the grooves 8a are formed in the portions where the resist is not formed.
f) Etching Applied to the Substrate

Next, the substrate 3 with the resist pattern 42 formed thereon, is introduced to a dry etching device. Then, etching is performed to the substrate 3 by a method descried in the <1. Manufacturing method of the master mold> e) Etching step applied to the substrate. At this time, etching treatment is applied to the substrate 3, with the resist pattern 42 as a mask, and as shown in FIG. 5(f), the lattice-shaped grooves 8 corresponding to the fine pattern are applied to the substrate 3. Before or after this event, the resist pattern 42 is removed by the above-mentioned resist release liquid.

Thus, as shown in FIG. 5(f), the grooving corresponding to the fine pattern is applied to the substrate 3.
g) Completion of the Working Replica

After the above-mentioned step, washing, etc., of the substrate 3 is performed as needed. Thus, the working replica 30 as shown in FIG. 5(g) is completed.

This embodiment can be suitably applied to the working replica 30 thus fabricated, and particularly to the patterned medium fabricated using the imprint technique.
<4. Manufacturing Method of BPM Based on the Working Replica>

A simple example of the manufacturing method of BPM is shown hereafter.

A release agent layer is formed over the working replica with a specific bit pattern transferred thereto.

Then, a soft magnetic layer, a non-magnetic orientation layer, and a magnetic recording layer formed of a magnetic body portion, and a protective layer, are formed on the substrate being the BPM, by sputtering in this order. Then, a lubricant layer is formed on the protective layer by a dip method.

Then, the surface of the substrate being BPM is coated with the photo-curing resist, then the resist layer is formed thereon, and thereafter the resist pattern is formed by exposure.

Thereafter, etching is performed, using the imprint resist layer with the bit pattern transferred thereto as a mask, and protrusions based on the bit pattern formed on the imprint mold structure 1, are formed on the magnetic recording layer, and the recesses are embedded with a non-magnetic material, to thereby flatten the surface. Thereafter, a protective film is formed to obtain the BPM.
<5. Effect of the Embodiment>

In this embodiment, exposure is performed so that the width of each line-shaped exposure candidate part is smaller than the width of each dot-shaped non-exposure part 7 in the specific cycle.

By exposing the portion “excluding the bit portion”, and further by setting the width of each line-shaped exposure candidate part 6 to be smaller than the width of each dot-shaped non-exposure part 7, relatively a larger amount of resist than conventional can be remained in the dot-shaped protrusion 1a portions. As a result, when etching is performed later to the substrate 1, relatively large dot-shaped protrusions 1a can be formed even if the resist is slightly lost.

As a result, a sufficient amount of resist can be remained in the dot-shaped protrusion 1a portions, and difficulty in forming the bit pattern can be reduced, and consequently the generation of the pattern defect can be suppressed.

Further, BPM having a sufficiently large magnetic material region, can be fabricated. It is not necessary to simultaneously expose a large bit corresponding to the sufficiently large magnetic material region every time the BPM is fabricated. Namely, it is sufficient to expose a small area (area of a portion excluding the bit portion) by electron beams, thus making it possible to considerably shorten a time required for the exposure.

As a result, the imprint mold capable of manufacturing BPM having high S/N, suppressing the generation of the pattern defect, and which can be manufactured relatively in a short time, can be provided.
<6. Modified Example>

Note that a technical range of the present invention is not limited to the above-mentioned embodiment, and includes various modifications or improvements in a range of deriving a specific effect obtained by constituting features of the invention and a combination thereof.

(Non-Exposure Portion in the Exposure Candidate Parts)

As simply described in the <1. Manufacturing method of the master mold> c) Exposure step, not all part of the “exposure candidate parts” of this embodiment should be necessarily exposed. For example, as shown in FIG. 2(a) and FIG. 2(b), a plurality of exposure candidate parts 6 are arranged to cross each other, and the exposure may not be performed in a crossed portion.

By thus performing exposure to the positive resist, the resist of a portion excluding crossing parts 6b, is dissolved in the exposure candidate parts 6. As a result, not only the resist of the dot-shaped non-exposure parts 7, but also the resist of the crossing parts 6b is remained.

If the etching is continuously performed to the substrate 1, it appears that the continuous grooves 8a cannot be formed due to the resist remained in the crossing parts 6b. However, if the resist pattern 22 remained in the crossing part 6b is small and therefore continuous grooves 8a can be formed on the substrate 1, they are removed when etching is performed to the substrate 1. As a result, the dot-shaped protrusions 1a can be finally formed on the main surface of the substrate 1 in such manner as being separated from each other for every one bit, even if not exposing the crossing parts 6b.
(Arrangement of Grooves)

As described above, the grooves 8a in the “lattice-shaped grooves” may be arranged so as to be formed by making a plurality of continuous straight lines cross each other. It is also acceptable that the grooves 8 are made to intersect each other without crossing each other, so as to form a trifurcate road.

Specifically, the continuous grooves 8a may be formed for every track in the circumferential direction, in such a manner that the tracks are connected to each other. The grooves 8a between the tracks may be provided only for connecting the tracks, and may not be continuous in a radius direction. At this time, when the grooves 8a between tracks are formed, the grooves 8a may be formed so as to be deviated by half of the specific cycle in the circumferential direction in each track.
(Non-Exposure Portion in the Exposure Candidate Parts and Arrangement of the Grooves)

The exposure step may be performed by combining the above-mentioned modified examples, to thereby fabricate the imprint mold. Specifically, as shown in FIG. 3(b) and FIG. 3(c), when the exposure candidate parts 6 are formed so as to connect the tracks, the exposure candidate parts 6 may be formed between tracks by being deviated by half of the specific cycle in the circumferential direction in each track.
(Shape of Bit)

Although the bit has a rectangular shape in the explanation of this embodiment, the bit may have the other shape. After all, the bit may have a circular shape or a polygonal shape in a planer view, provided that this is a suitable shape as a magnetic material portion in the BPM.

When the bit has substantially a circular shape in a planer view, etching may be performed to the substrate 1 by the method of this embodiment.

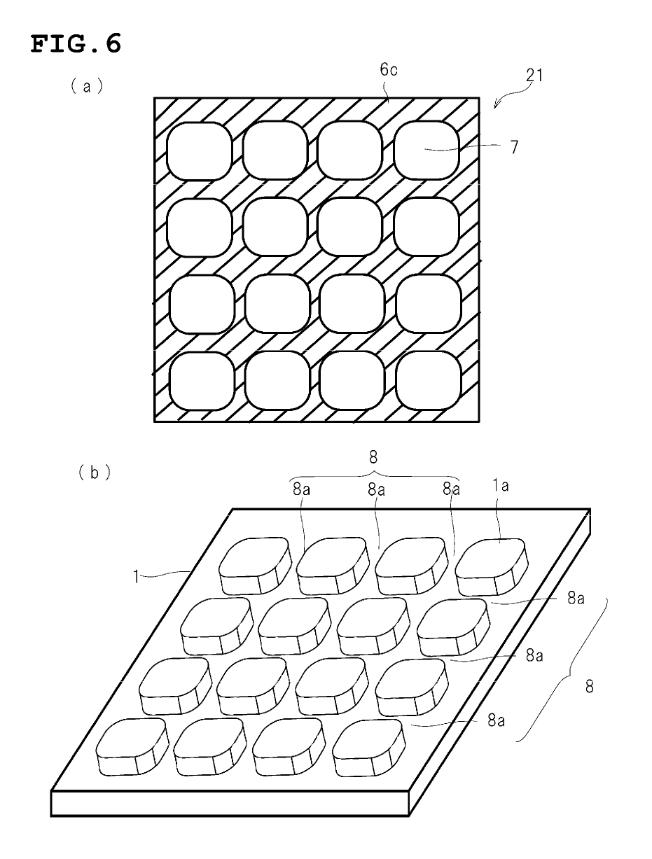

Specifically at the timing of the etching, when the exposure candidate parts 6 are entirely exposed, exposure is repeatedly performed to the portion where the exposure candidate parts 6 cross each other. As a result, in the development step, the resist of an unexpectedly large area is removed in the portion where the exposure candidate parts 6 cross each other (FIG. 6(a)). As a result, the resist of the portion indicated by symbol 6c (oblique line portion) is removed, and a corner portion of each resist pattern 22 is rounded, although it is formed into a rectangular shape in a planer view. As a result, the corner portion of the dot-shaped protrusion 1a on the substrate 1 is also etched (FIG. 6(b)).

As described above, by controlling an etching condition, substantially circular dot-shaped protrusions 1a in a planer view, can be relatively easily formed.

Meanwhile, when the bit shape is substantially a rectangular shape in a planer view, as shown in FIG. 2(a) and FIG. 2(b), the portions 6b where the exposure candidate parts 6 cross each other, are preferably set as non-exposure portions in the positive resist. By thus performing exposure, although the resist remains in the portions 6b where the exposure candidate parts 6 cross each other as described above, the resist is removed in the middle of the etching applied to the substrate 1. The timing of removing the resist is utilized. Namely, the resist remains in the portions 6b where the exposure candidate parts 6 cross each other in the middle of the etching applied to the substrate 1. Therefore, unlike a case that the exposure candidate parts 6 are entirely exposed, to say nothing of the repeated exposure, the exposure itself is not performed to the portions 6b where the exposure candidate parts 6 cross each other. As a result, the resist of the portions 6b where the exposure candidate parts 6 cross each other, is removed for the first time when the etching is applied to the substrate 1, and the etching applied to the substrate 1 is completed before the corner portion of each dot-shaped protrusion la in the substrate 1 is etched.

As described above, by controlling the etching condition, the dot-shaped protrusion 1a having substantially a rectangular shape in a planer view, can be relatively easily formed.
(Negative Resist)

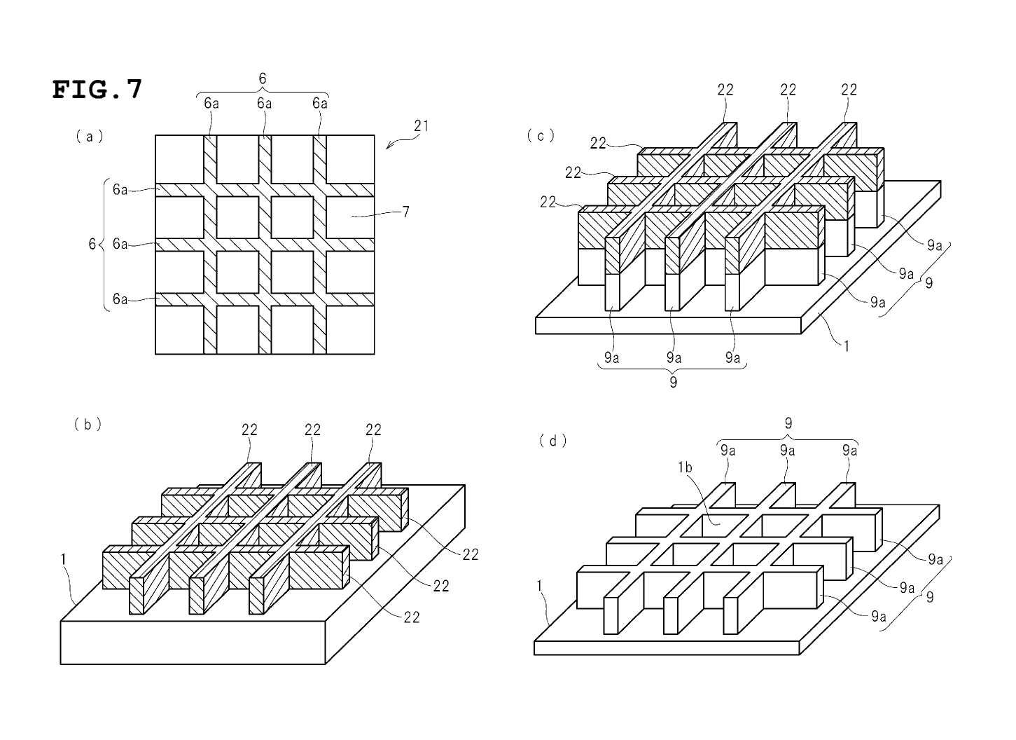

In this embodiment, explanation is given for a case that the positive resist is used. However, the effect of the present invention can be obtained by using the negative resist. In addition, a special effect can also be obtained when the negative resist is used. Explanation is given for a case that the negative resist is used, using FIG. 7.

As shown in FIG. 7(a), when the negative resist is used for creating the master mold 10, the resist of the exposed portion is remained. As a result, as shown in FIG. 7(b), lattice-shaped wall-like resist pattern 22 formed by making a plurality of continuous line-shaped walls cross each other, are formed in the above-mentioned d) development step. As shown in FIG. 7(c), by etching the substrate 1 using the resist pattern 22 having such a shape as a mask in the e) etching step, lattice-shaped wall parts 9 formed by making a plurality of continuous planer view line-shaped walls 9a cross each other, are finally formed on the main surface of the substrate, as shown in FIG. 7(d). Then, the portions surrounded by the lattice-shaped wall parts 9 are the shaved portions (dot-shaped recess portions 1b) on the main surface of the substrate 1.

In this case, the dot-shaped recesses 1b are the base of the magnetic material region in the BPM. Then, the dot-shaped recesses 1b are formed at a specific cycle in a specific direction on the main surface of the substrate 1. At this time, similarly to the case of the positive resist, the width of each line-shaped wall 9a is set to be smaller than the width of each dot-shaped recess 1b in the specific cycle.

With this structure, similarly to the case of the positive resist, the mold capable of manufacturing the BPM having high S/N, and suppressing the generation of the pattern defect, can be provided.

Further, when the negative resist is used, continuous resist pattern like beams of a ceiling (so-called continuous resist walls) can be formed in a case of forming the resist pattern 22. Thus, since the resist walls are continuously formed, fall-down of the resist pattern 22 can be suppressed. As a result, pattern fall in a case of etching the substrate 1, can be suppressed, and the generation of the pattern defect can be surely suppressed.

Note that even in a case of using the negative resist, a preferable example in the case of using the positive resist described in this embodiment (the length of the specific cycle, the kind of the substrate, and the arrangement and the shape, etc., of the groove) can be basically used, and effects in these structures are the same.

However, when the negative resist is used, there is a meaning in forming the continuous walls of the resist. Therefore, unlike the case of the positive resist, it is preferable to actually expose the overall exposure candidate parts 6. Namely, preferably the whole part of the exposure candidate parts 6 are used as the “exposure parts”, and the exposure parts are formed into a lattice shape, and the non-exposure parts 7 may be surrounded by the lattice-shaped exposure parts.
(Other Modified Examples)

Modified examples other than the above-mentioned examples will be listed hereafter.

First, regarding the shape of each substrate 1, 3, the substrate 1 may have the shape other than the wafer shape, and may be the substrate processed into the rectangular shape, polygonal shape, semi-circular shape viewed from a planar surface (upper surface), or processed into the rectangular shape or a trapezoidal shape viewed from a side face, and preferably may have the shape easily fixed to a print device stably as a mold with high precision. Further, the substrate may have the trapezoidal shape (mesa structure or a pedestal) on the main surface, with a height of a peripheral edge part slightly lower than a pattern formation region on the main surface of the mold.

Further, the track may not have a concentric circular shape, and may be a straight track or may be a curved track other than a concentric track.

Regarding the transparency of the substrates 1 and 3, each substrate is preferably a transparent or semi-transparent substrate, in consideration of a facility of fabricating the working replica. Further, regarding the material of each substrate 1, 3, the substrate is made of quartz, sapphire, or metal such as Si, plastic, and ceramics, etc., or a combination of them. However, the material or the structure does not matter, if it can be used as the master mold 10.

Further, the resist in this embodiment preferably has reactivity when exposure is performed thereto by irradiation of an energy beam. Specifically, the resist requiring the development by the developing agent may be used, and the resist having sensitivity to UV-ray, X-ray, electron beam, ion beam, and proton beam, etc., may also be used.

Note that in this embodiment, although the resist layer is directly provided on the substrate, another layer may be provided between the substrate and the resist layer. As another layer, a hard mask including a conductive layer and an antioxidant layer, and an adhesive layer can be given. The “hard mask” called here includes a single or a plurality of layers, and indicates a layer-shaped hard mask used for etching the surface of the substrate to form a groove. Note that the antioxidant layer may also be used as the conductive layer. In this case, the conductive layer can be omitted.

Further, this embodiment shows an example of forming the working replica 30 from the master mold 10 by the imprint method. In addition to this case, the working replica 30 of this embodiment may be formed from a working replica formed by transferring a fine pattern of the master mold to another molded material, and from a working replica formed by further transferring the fine pattern of this working replica to another molded material. This is because even if this working replica is deformed or broken, the working replica can be fabricated if the master mold is safe.

Further, in the etching of this embodiment, only a part of the etching may be a wet-etching, and a dry-etching may be performed in other etching, or the wet-etching or the dry etching may be performed in all etchings. Further, the wet-etching may be introduced according to a pattern size, in such a way that the wet-etching is performed in a micron-order stage in a case that the pattern size is a micron-order, and the dry-etching is performed in a nano-order stage.

Preferable supplementary descriptions of this embodiment are described hereafter.

### [Supplementary Description 1]

An imprint mold for manufacturing the bit-patterned medium with an imprint method, wherein dot-shaped protrusions are formed on a main surface of a substrate, so as to be a base of a magnetic material region in the bit-patterned medium, with the dot-shaped protrusions formed at a specific cycle in a specific direction on the main surface of the substrate,
wherein the dot-shaped protrusions are formed by being surrounded by lattice-shaped grooves formed by shaving the main surface of the substrate and making a plurality of continuous planar view line-shaped grooves cross each other; and
a width of each line-shaped groove is smaller than a width of each dot-shaped protrusion in the specific cycle,
wherein the specific cycle is less than 1 μm, and an area of the dot-shaped protrusions in the specific cycle is larger than ⅓ of an area of the lattice-shaped grooves in the specific cycle.

### [Supplementary Description 2]

There is provided the imprint mold for manufacturing a bit patterned medium, wherein the lattice-shaped grooves are formed by making a plurality of planer view straight grooves cross each other.

### [Supplementary Description 3]

There is provided the imprint mold for manufacturing a bit patterned medium with an imprint method, wherein dot-shaped recesses are formed on a main surface of a substrate, so as to be a base of a magnetic material region in the bit-patterned medium, with the dot-shaped recesses formed at a specific cycle in a specific direction on the main surface of the substrate,
wherein the dot-shaped recesses are formed by surrounding a shaped portion on the main surface of the substrate by lattice-shaped wall parts formed by making a plurality of continuous planar view line-shaped walls cross each other; and
a width of each line-shaped wall is smaller than a width of each dot-shaped recess in the specific cycle,
wherein the specific cycle is less than 1 μm, and an area of the dot-shaped recesses in the specific cycle is larger than ⅓ of an area of the lattice-shaped grooves in the specific cycle.

### [Supplementary Description 4]

There is provided the imprint mold for manufacturing a bit patterned medium, wherein the lattice-shaped wall parts are formed by making a plurality of planer-view straight walls cross each other.

### [Supplementary Description 5]

There is provided the imprint mold for manufacturing a bit patterned medium, wherein the specific cycle is 25 nm or less, and the width of each line-shaped wall is ⅔ or less of the width of each dot-shaped recess.

### [Supplementary Description 6]

There is provided a manufacturing method of an imprint mold for manufacturing a bit patterned medium, wherein the substrate is a transparent or semi-transparent substrate.

### [Supplementary Description 7]

There is provided an imprint mold for manufacturing a bit patterned medium, wherein the substrate is made of quartz.

### [Supplementary Description 8]

There is provided the imprint mold for manufacturing a bit patterned medium, wherein dot-shaped recesses are formed on a main surface of a substrate, so as to be a base of a magnetic material region in a bit patterned medium, with the dot-shaped recesses formed in a specific direction at a specific cycle of 25 nm or less on the main surface of the substrate, and the substrate is a transparent or semi-transparent substrate,
wherein the dot-shaped recesses are formed by surrounding a shaved portion on the main surface of the substrate by lattice-shaped wall parts formed by making a plurality of continuous planer-view line-shaped walls cross each other, and
a width of each line-shaped wall part is ⅔ or less of a width of each dot-shaped recess in the specific cycle.

### [Supplementary Description 9]

There is provided a manufacturing method of an imprint mold for manufacturing a bit patterned medium with an imprint method, wherein dot-shaped protrusions are formed on a main surface of a substrate in such a manner as being separated for every one bit, so as to be a base of a magnetic material region in the bit-patterned medium, with the dot-shaped protrusions formed in a specific direction at a specific cycle on the main surface of the substrate, the method including:
coating a positive resist so as to cover the main surface of the substrate;
performing lattice-shaped exposure after coating, to the main surface of the substrate covered with the positive resist by making a plurality of line-shaped exposure candidate parts cross each other, and forming lattice-shaped exposure candidate parts and dot-shaped non-exposure parts surrounded by the lattice-shaped exposure candidate parts;
forming a resist pattern by developing the positive resist after exposure; and
forming a bit-pattern including dot-shaped protrusions on the main surface of the substrate by etching, after development,
wherein in the exposure, the exposure is performed so that a width of each line-shaped exposure candidate part is smaller than a width of each dot-shaped non-exposure part in the specific cycle, and
the dot-shaped protrusions are finally formed by line-shaped exposure, on the main surface of the substrate in such a manner as being separated for every one bit,
wherein the specific cycle is less than Ulm, and an area of the dot-shaped recesses in the specific cycle is larger than ⅓ of an area of the lattice-shaped grooves in the specific cycle.

### [Supplementary Description 10]

There is provided the imprint mold for manufacturing a bit patterned medium, wherein the lattice-shaped exposure is performed by making a plurality of planar view straight exposure candidate parts cross each other. [Supplementary Description 11]

There is provided a manufacturing method of an imprint mold for manufacturing a bit patterned medium with an imprint method, wherein dot-shaped recesses are formed on a main surface of a substrate in such a manner as being separated for every one bit, so as to be a base of a magnetic material region in the bit-patterned medium, with the dot-shaped recesses formed in a specific direction at a specific cycle on the main surface of the substrate, the method including:
coating a negative resist so as to cover the main surface of the substrate;
performing lattice-shaped exposure after coating, to the main surface of the substrate covered with the negative resist by making a plurality of line-shaped exposure parts cross each other, and forming lattice-shaped exposure parts and dot-shaped non-exposure parts surrounded by the lattice-shaped exposure parts;
developing the negative resist after exposure, to thereby form a resist pattern; and
forming a bit pattern including dot-shaped recesses by etching after development, on the main surface of the substrate,
wherein in the exposure, the exposure is performed so that a width of each line-shaped exposure part is smaller than a width of each dot-shaped non-exposure part in the specific cycle, and
by the line-shaped exposure, the dot-shaped recesses are finally formed on the main surface of the substrate in such a manner as being separated for every one bit, and
the exposure is performed by electron beam drawing over the main surface of the substrate covered with the negative resist. [Supplementary Description 12]

The manufacturing method of an imprint mold for manufacturing a bit patterned medium, wherein the specific cycle is 25 nm or less and the width of each line-shaped exposure candidate part is set to ⅔ or less of the width of each dot-shaped non-exposure part. [Supplementary Description 13]

There is provided the manufacturing method of an imprint mold for manufacturing a bit patterned medium, wherein the substrate is a transparent or semi-transparent substrate. [Supplementary Description 14]

There is provided the manufacturing method of an imprint mold for manufacturing a bit patterned medium, wherein the substrate is made of quartz. [Supplementary Description 15]

There is provided the manufacturing method of an imprint mold for manufacturing a bit patterned medium with an imprint method, wherein dot-shaped recesses are formed on a main surface of a substrate, so as to be a base of a magnetic material region in the bit patterned medium, with the dot-shaped recesses formed in a specific direction at a specific cycle of 25 nm on the main surface of the substrate, and the substrate is a transparent or semi-transparent substrate, the method including:
coating a negative resist so as to cover the main surface of the substrate;
performing lattice-shaped exposure by electron beams after coating, to the main surface of the substrate covered with the negative resist by making a plurality of line-shaped exposure candidate parts cross each other, to thereby form lattice-shaped exposure candidate parts and dot-shaped non-exposure parts surrounded by the lattice-shaped exposure candidate parts;
developing the negative resist after exposure, to thereby form a resist pattern; and
forming a bit pattern by etching after development, on the main surface of the substrate,
wherein in the exposure, exposure is performed so that a width of each line-shaped exposure candidate part is ⅔ or less of a width of each dot-shaped non-exposure part, and
the dot-shaped recesses are finally formed by line-shaped exposure, on the main surface of the substrate in such a manner as being separated for every one bit.

### DESCRIPTION OF SIGNS AND NUMERALS

1 Substrate (for master mold)

10 Master mold

21 Resist layer

21a Residual film layer

22 Resist pattern

3 Substrate (for working replica)

30 Working replica

41 Resist layer

41a Residual film layer

42 Resist pattern

5 Mold release layer

6 Exposure candidate part

6a Portion actually exposed in the exposure candidate part

6b Portion not actually exposed in the exposure candidate part (portion or intersection where the exposure candidate parts are crossed each other)

6c Portion where resist is removed

7 Non-exposure part

8 Lattice-shaped groove

8a Line-shaped groove

9 Lattice-shaped wall part

9a Line-shaped wall

1. An imprint mold for manufacturing the bit-patterned medium with an imprint method, wherein dot-shaped protrusions are formed on a main surface of a substrate, so as to be a base of a magnetic material region in the bit-patterned medium, with the dot-shaped protrusions formed at a specific cycle in a specific direction on the main surface of the substrate,
wherein the dot-shaped protrusions are formed by being surrounded by lattice-shaped grooves formed by shaving the main surface of the substrate and making a plurality of continuous planar view line-shaped grooves cross each other; and
a width of each line-shaped groove is smaller than a width of each dot-shaped protrusion in the specific cycle.

2. The imprint mold for manufacturing a bit patterned medium according to claim 1, wherein the specific cycle is 25 nm or less, and the width of each line-shaped groove is ⅔ of the width of each dot-shaped protrusion.

3. The imprint mold for manufacturing a bit patterned medium according to claim 1, wherein the substrate is a transparent or semi-transparent substrate.

4. The imprint mold for manufacturing a bit patterned medium according to claim 1, wherein the substrate is made of quartz.

5. The imprint mold, for manufacturing a bit patterned medium with an imprint method according to claim 1, wherein dot-shaped protrusions are formed on a main surface of a substrate, so as to be a base of a magnetic material region in the bit-patterned medium, with the dot-shaped protrusions formed at a specific cycle of 25 nm or less in a specific direction on the main surface of the substrate, and the substrate is a transparent or a semi-transparent substrate,
wherein the dot-shaped protrusions are formed by being surrounded by lattice-shaped grooves formed by shaving the main surface of the substrate and making a plurality of continuous planar view line-shaped grooves cross each other; and
a width of each line-shaped groove is ⅔ of a width of each dot-shaped protrusion in the specific cycle.

6. An imprint mold for manufacturing a bit patterned medium with an imprint method, wherein dot-shaped recesses are formed on a main surface of a substrate, so as to be a base of a magnetic material region in the bit-patterned medium, with the dot-shaped protrusions formed at a specific cycle in a specific direction on the main surface of the substrate,
wherein a width of each line-shaped wall is smaller than a width of each dot-shaped recess in the specific cycle.

7. An imprint mold for manufacturing a bit patterned medium, wherein an imprint mold is fabricated with an imprint method, using the imprint mold for manufacturing a patterned medium according to claim 1, as an original mold.

8. A manufacturing method of an imprint mold for manufacturing a bit patterned medium with an imprint method, wherein dot-shaped protrusions are formed on a main surface of a substrate, so as to be a base of a magnetic material region in the bit-patterned medium, with the dot-shaped protrusions formed at a specific cycle in a specific direction on the main surface of the substrate, the method comprising:
coating a positive resist so as to cover the main surface of the substrate;
performing lattice-shaped exposure after coating, to the main surface of the substrate covered with the positive resist by making a plurality of line-shaped exposure candidate parts cross each other, and forming lattice-shaped exposure candidate parts and dot-shaped non-exposure parts surrounded by the lattice-shaped exposure candidate parts;
forming a resist pattern by developing the positive resist after exposure; and
forming a bit-pattern including dot-shaped protrusions on the main surface of the substrate by etching, after development,
wherein in the exposure, the exposure is performed so that a width of each line-shaped exposure candidate part is smaller than a width of each dot-shaped non-exposure part in the specific cycle, and the dot-shaped protrusions are finally formed by line-shaped exposure, on the main surface of the substrate in such a manner as being separated for every one bit.

9. The manufacturing method of an imprint mold for manufacturing a bit patterned medium according to claim 8, wherein the exposure is performed by electron beam drawing over a main surface of a substrate covered with the positive resist.

10. The manufacturing method of an imprint mold for manufacturing a bit patterned medium according to claim 8, wherein the specific cycle is set to 25 nm or less, and the width of each line-shaped exposure candidate part is set to ⅔ or less of the width of each dot-shaped non-exposure part.

11. The manufacturing method of an imprint mold for manufacturing a bit patterned medium according to claim 8, wherein the substrate is a transparent or semi-transparent substrate.

12. The manufacturing method of an imprint mold for manufacturing a bit patterned medium according to claim 8, wherein the substrate is made of quartz.

13. The manufacturing method of an imprint mold for manufacturing a bit patterned medium according to claim 8 with an imprint method, wherein dot-shaped protrusions are formed on a main surface of a substrate, so as to be a base of a magnetic material region in the bit patterned medium, with the dot-shaped protrusions formed in a specific direction at a specific cycle of 25 nm on the main surface of the substrate, and the substrate is a transparent or semi-transparent substrate, the method comprising:
coating a positive resist so as to cover the main surface of the substrate;
performing lattice-shaped exposure after coating, to the main surface of the substrate covered with the positive resist by making a plurality of line-shaped exposure candidate parts cross each other, and forming lattice-shaped exposure candidate parts and dot-shaped non-exposure parts surrounded by the lattice-shaped exposure candidate parts;
forming a resist pattern by developing the positive resist after exposure; and
forming a bit-pattern on the main surface of the substrate by etching after development,
wherein in the exposure, the exposure is performed so that a width of each line-shaped exposure candidate part is ⅔ of a width of each dot-shaped non-exposure part in the specific cycle, and
the dot-shaped protrusions are finally formed by line-shaped exposure, on the main surface of the substrate in such a manner as being separated for every one bit.

14. A manufacturing method of an imprint mold for manufacturing a bit patterned medium with an imprint method, wherein dot-shaped recesses are formed on a main surface of a substrate in such a manner as being separated for every one bit, so as to be a base of a magnetic material region in the bit-patterned media, with the dot-shaped recesses formed in a specific direction at a specific cycle on the main surface of the substrate, the method comprising:
coating a negative resist so as to cover the main surface of the substrate;
performing lattice-shaped exposure after coating, to the main surface of the substrate covered with the negative resist by making a plurality of continuous line-shaped exposure parts cross each other, and forming lattice-shaped exposure parts and dot-shaped non-exposure parts surrounded by the lattice-shaped exposure parts;
forming a lattice-shaped resist pattern by developing the negative resist after exposure; and
forming a bit-pattern including dot-shaped recesses on the main surface of the substrate by etching, after development,
wherein in the exposure, the exposure is performed so that a width of each line-shaped exposure part is smaller than a width of each dot-shaped non-exposure part in the specific cycle, and
the dot-shaped recesses are finally formed by line-shaped exposure, on the main surface of the substrate in such a manner as being separated for every one bit.

15. A manufacturing method of an imprint mold for manufacturing a bit-patterned medium, wherein the imprint mold fabricated by the manufacturing method of an imprint mold for manufacturing a patterned medium described in claim 8, is used as an original mold, to thereby fabricate the imprint mold by imprint.
